(19) United States
(12) Patent Application Publication
(10) Pub. No.: US 2021/0098533 A1
(43) Pub. Date: Apr. 1, 2021

(54) VERTICAL RESISTIVE RANDOM ACCESS MEMORY

(71) Applicant: QUALCOMM Incorporated, San Diego, CA (US)

(72) Inventors: Bin YANG, San Diego, CA (US); Xia LI, San Diego, CA (US); Gengming TAO, San Diego, CA (US)

(21) Appl. No.: 16/585,216

(22) Filed: Sep. 27, 2019

(51) Int. Cl. H01L 27/24; H01L 45/00

(52) U.S. Cl. CPC H01L 27/2463; H01L 45/1233; H01L 45/08; H01L 45/146; H01L 45/1608; H01L 45/1253

(57) ABSTRACT

Certain aspects of the present disclosure generally relate to a vertical resistive random access memory (RRAM). The vertical RRAM generally includes a planar substrate layer and a plurality of fin-like metal-insulator-metal (MIM) structures extending orthogonally above the substrate layer.

### TECHNICAL FIELD

Certain aspects of the present disclosure generally relate to electronic components and, more particularly, to resistive random access memory (RRAM).

### BACKGROUND

Resistive random access memory (RRAM) devices use resistance-based storage elements to store information. For example, a resistance-based storage element may be programmed to a high resistance state to indicate a particular value (e.g., a logic “1” value) or to a low resistance state to indicate another value (e.g., a logic “0” value). The state of the resistance-based storage element may be sensed by applying a voltage to the resistance-based storage element and by sensing a current through the resistance-based storage element that results from the voltage. The current may indicate (by Ohm's law) the state of the resistance-based storage element.

In some cases, the resistance-based storage elements of RRAM devices may be implemented by generating defects in a thin oxide layer located between two electrode layers. These defects in the oxide layer may be referred to as “oxygen vacancies,” which are oxide bond locations where the oxygen has been removed. Oxygen vacancies may be charged and drift in the presence of an electric field, analogous to the motion of holes and electrons in semiconductors.

RRAM devices may, in some cases, be associated with high costs of fabrication. For example, an RRAM device may include multiple interconnects to access the resistance-based storage elements, such as a crossbar array of metal wires. The metal wires may intersect near each resistance-based storage element to enable access to each resistance-based storage element. The crossbar array may utilize a large circuit area of an integrated circuit and may be complicated to operate in some cases. Further, the crossbar array may be fabricated using a mask, which increases fabrication cost.

### SUMMARY

Certain aspects of the present disclosure are generally directed to a vertical resistive random access memory (RRAM). The vertical RRAM generally includes a planar substrate and a plurality of metal-insulator-metal (MIM) structures extending orthogonally above the planar substrate, wherein: the plurality of MIM structures are laterally disposed with respect to each other across at least a portion of the planar substrate; each MIM structure comprises a first electrode layer, a resistive-switching material layer, and a second electrode layer; each of the first electrode layer, the resistive-switching material layer, and the second electrode layer comprises a longer dimension and a shorter dimension; the resistive-switching material layer is disposed substantially between the first electrode layer and the second electrode layer; and the longer dimension of each of the first electrode layer, the resistive-switching material layer, and the second electrode layer extends orthogonally above the planar substrate in a same direction.

Certain aspects of the present disclosure generally relate to a method for fabricating a vertical RRAM device. The method generally includes forming a plurality of MIM structures extending orthogonally above a planar substrate, wherein: the plurality of MIM structures are laterally disposed with respect to each other across at least a portion of the planar substrate; each MIM structure comprises a first electrode layer, a resistive-switching material layer, and a second electrode layer; each of the first electrode layer, the resistive-switching material layer, and the second electrode layer comprises a longer dimension and a shorter dimension; the resistive-switching material layer is disposed substantially between the first electrode layer and the second electrode layer; and the longer dimension of each of the first electrode layer, the resistive-switching material layer, and the second electrode layer extends orthogonally above the planar substrate in a same direction.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a cross-sectional view of a conventional resistive random access memory (RRAM).

FIG. 2 illustrates an example cross-section of a vertical resistive random access memory (RRAM), according to certain aspects presented herein.

FIGS. 3A-M illustrate example operations for fabricating vertical RRAM, in accordance with certain aspects of the present disclosure.

FIGS. 4A-6B illustrate different options for providing connections to RRAM cells of a vertical RRAM, in accordance with certain aspects of the present disclosure.

FIG. 7 is a flow diagram illustrating example operations for fabricating a vertical RRAM, in accordance with certain aspects of the present disclosure.

### DETAILED DESCRIPTION

Certain aspects of the present disclosure are generally directed to a vertical resistive random access memory (RRAM). The vertical RRAM generally includes a planar substrate layer and a plurality of fin-like metal-insulator-metal (MIM) structures extending orthogonally above the substrate layer.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

Certain terminology may also be used in the following description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

### Example Planar RRAM

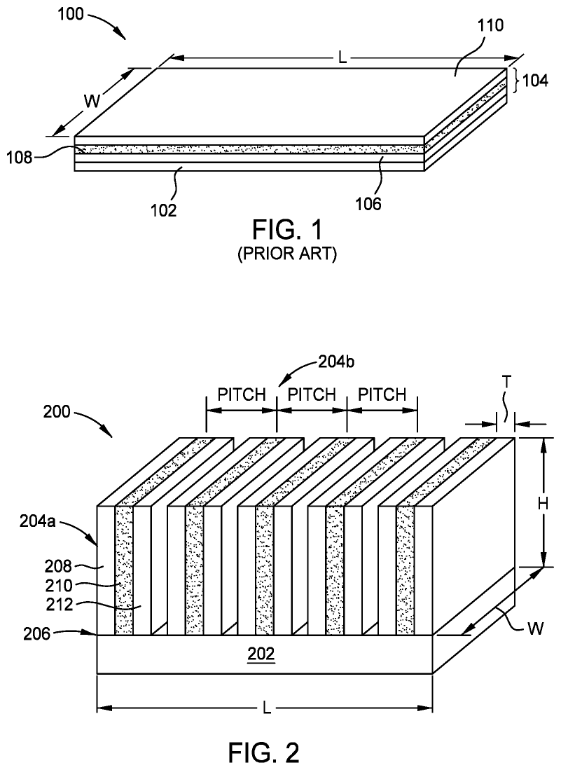

FIG. 1 illustrates a three-dimensional cross-section of a conventional planar RRAM 100. As illustrated, the RRAM 100 may comprise a substrate layer 102 with dimensions L×W, where L is length and W is width. The substrate layer 102 may be a substrate employed in a semiconductor process, such as a silicon substrate or any other suitable material (e.g., glass, ceramic, aluminum oxide (Al₂O₃), etc.). FIG. 1 illustrates the substrate layer 102 as a plain rectangle in order to simplify the illustration, and is not intended to be limiting. For example, there may be other shapes and sizes of the substrate layer 102, as well as intervening layers.

As illustrated, a planar metal-insulator-metal (MIM) structure 104, forming a RRAM cell, may be disposed on top of the substrate layer 102. For example, as illustrated, the MIM structure 104 may comprise a first electrode layer 106, a resistive-switching material layer 108, and a second electrode layer 110. The first electrode layer 106, the second electrode layer 110, and the resistive-switching material layer 108 have an in-plane (or “horizontal”) configuration (e.g., where read and write currents are generated “horizontally” to, or substantially parallel to, a top surface of the substrate layer 102.

The resistive-switching material layer 108 may comprise a dielectric material and, thus, may normally be insulating. However, when a sufficient voltage (known as a “forming voltage”) is applied between the first electrode layer 106 and the second electrode layer 110, one or more conductive pathways will form in the resistive-switching material layer 108. Through the appropriate application of various voltages (e.g. a set voltage and reset voltage), the conductive pathways may be modified to form a high resistance state or a low resistance state. For example, a resistive-switching material may change from a first resistivity to a second resistivity upon the application of a set voltage, and from the second resistivity back to the first resistivity upon the application of a reset voltage.

An RRAM cell may be regarded as storing a logical bit. Where the resistive-switching element has increased resistance, the RRAM cell may be regarded as storing a “0” bit (a logical low state); where the resistive-switching element has reduced resistance, the RRAM cell may be regarded as storing a “1” bit (a logical high state), and vice versa. In some cases, circuitry may be used to read the resistive state of the resistive-switching element by applying a read voltage to the two electrodes and measuring the corresponding current through the resistive-switching element. If the current through the resistive-switching element is greater than some predetermined baseline current, the resistive-switching element is deemed to be in a reduced resistance state, and therefore the RRAM cell is storing a logical “1.” On the other hand, if the current through the resistive-switching element is less than some predetermined baseline current, then the resistive-switching element is deemed to be in an increased resistance state, and therefore the RRAM cell is storing a logical “0.” It should be noted that the resistive states and corresponding logical values are only meant as examples and that the high resistive state could correspond to a logical “1” and the low resistive state could correspond to a logical “0.”

Conventional RRAM offers much faster, bit-alterable, erase-free operation and may deliver 100× lower read latency and 1000× faster write performance than traditional flash memory. Additionally RRAM may be architected with smaller pages to reduce read and write latencies, lower energy, and increased lifetime of the storage solutions. However, conventional RRAM structures, such as the RRAM 100 illustrated in FIG. 1, come with certain disadvantages. For example, as illustrated in FIG. 1, the RRAM 100 consumes a large amount of area, which may limit RRAM scaling size/memory density, as well as be costly to produce.

Thus, to help alleviate these issues with conventional RRAM structures, aspects of the present disclosure provide a vertical RRAM structure (as well as techniques for fabricating the same) that increases RRAM density and lowers fabrication cost compared to conventional RRAM structures. For example, the vertical RRAM structure described herein may take advantage of an advanced complementary metal-oxide-semiconductor (CMOS) self-aligned process, which may lower fabrication cost associated with the RRAM and allows for more accurate control over RRAM cell pitch (e.g., the spacing between RRAM cells in RRAM).

### Example Vertical RRAM

FIG. 2 illustrates an example cross-section of a vertical RRAM 200, according to certain aspects presented herein. As illustrated, the vertical RRAM 200 may include a planar substrate 202, which may be composed of any suitable semiconductive or insulative material, such as silicon, glass, ceramic, or aluminum oxide (Al₂O₃). In some cases, the substrate 202 may comprise a first layer and a second layer deposited on top of the first layer (e.g., as shown and described in greater detail below). In some cases, the first layer comprises one of silicon, glass, ceramic, or aluminum oxide. Additionally, in some cases, the second layer comprises silicon dioxide.

Additionally, as illustrated, the vertical RRAM 200 may include a plurality of fin-like metal-insulator-metal (MIM) structures 204 coupled to, and extending orthogonally above, an upper surface plane 206 of the substrate 202. According to certain aspects, each MIM structure of the plurality of MIM structures 204 may make up a single RRAM cell (also referred to herein as a memory cell). Further, as illustrated, the plurality of MIM structures 204 may be laterally disposed (e.g., horizontally stacked) with respect to each other across the surface plane 206 of the substrate 202. For example, as illustrated, a first MIM structure 204a may be disposed at an edge of the surface plane 206 of the substrate 202. Additionally, a second MIM structure 204b may be disposed laterally adjacent to the first MIM structure 204a across the surface plane 206 of the substrate 202, and so on.

According to aspects, each MIM structure 204 may comprise a first electrode layer 208, a resistive-switching material layer 210 (e.g., a suitable dielectric layer, which may comprise a metal oxide layer), and a second electrode layer 212. As illustrated, the resistive-switching material layer 210 may be disposed substantially between the first electrode layer 208 and the second electrode layer 212, forming a RRAM cell.

In some cases, each of the first electrode layer 208 and the second electrode layer 212 may be approximately 2-5 nanometers (nm) thick and made from any of various suitable electrically conductive materials, such as titanium nitride (TiN). Additionally, the resistive-switching material layer 210 may be approximately 1 nm thick and made from any of various suitable materials capable of having oxygen vacancies, such as hafnium oxide (HfO₂) and/or titanium oxide (TiO₂).

Further, as illustrated, each of the cross-sections of the first electrode layer 208, the resistive-switching material layer 210, and the second electrode layer 212 may comprise a longer dimension (e.g., shown as height, H, in FIG. 2) and a shorter dimension (e.g., shown as thickness T, in FIG. 2, which may also refer to the width of each layer, as opposed to the depth of each layer matching the width of the substrate 202). According to aspects, the longer dimension of each of the cross-sections of the first electrode layer, the resistive-switching material layer, and the second electrode layer may extend orthogonally above the surface plane 206 of the substrate 202, forming the fin-like MIM structure 204. The depth (width W) of each of the first electrode layer 208, the resistive-switching material layer 210, and the second electrode layer 212 may extend into and/or out of the page of the cross-section of FIG. 2. The depth may be greater than the height H.

Further, in some cases, a first dielectric layer may be deposited between two or more MIM structures (or RRAM cell) of the plurality of MIM structures 204, separating, for example, one MIM structure (e.g., the first MIM structure 204a) from another MIM structure (e.g., the second MIM structure 204b). In some cases, the distance between each MIM structure 204 may be approximately 10 nm, resulting in a “pitch” between MIM structures 204 of approximately 15-20 nm. For example, “pitch” may refer to the distance between the middle of a first MIM structure (e.g., MIM structure 204a) and the middle of a second MIM structure (e.g., MIM structure 204b).

In some cases, as will be shown in greater detail below, the first electrode layer 208 and the resistive-switching material layer 210 may be disposed directly adjacent to the substrate 202. However, in some cases, the resistive-switching material layer 210 may separate the second electrode layer 212 from the substrate 202.

According to aspects, when a sufficient voltage (e.g., “forming voltage”) is applied to the first electrode layer 208 and the second electrode layer 212, one or more conductive pathways will form in the resistive-switching material layer 210, reducing the resistance (i.e., increasing the conductance) between the first electrode layer 208 and the second electrode layer 212. Through the appropriate application of various voltages (e.g., a set voltage and a reset voltage), the conductive pathways may be modified to form a high resistance state or a low resistance state, allowing a logical value (e.g., “0” or “1”) to be stored in the resistive-switching material 210.

As can be seen, the fin-like MIM structures 204 allow the vertical RRAM 200 to increase the RRAM cell density by a factor of N (e.g., N=2, 3, 4, etc.) as compared to the conventional planar RRAM 100 of FIG. 1. For example, for a same wafer area (L×W), the vertical RRAM 200 of FIG. 2 increases the density of RRAM cells by five as compared to the RRAM 100 of FIG. 1. For example, as illustrated in FIG. 1, one may conceptualize the RRAM 100 as a book (e.g., RRAM cell) lying flat on a surface of a table (e.g., representing the wafer size L×W). Accordingly, as illustrated, only a single RRAM cell may fit on a wafer size L×W. In contrast, one may conceptualize the vertical RRAM 200 as a plurality of books (e.g., RRAM cells) standing up on the same table of size L×W. As can be seen, for the same wafer size of L×W, the vertical RRAM 200 is able to increase the RRAM cell density by a factor of 5 as compared to the conventional planar RRAM 100.

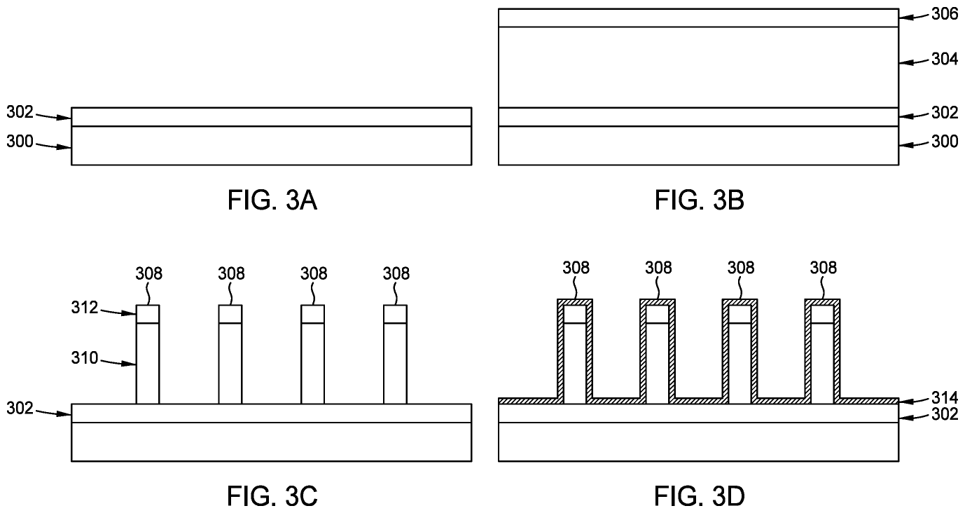

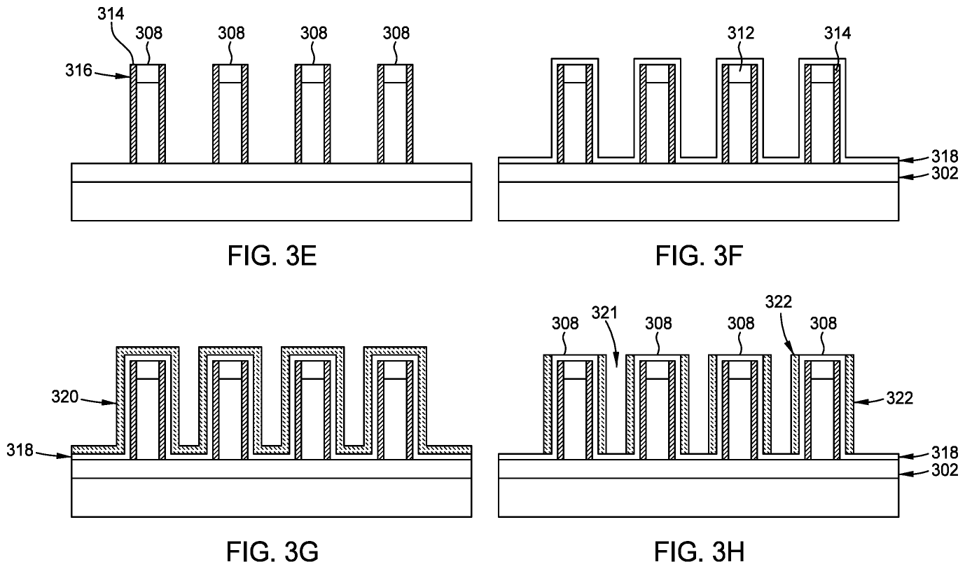

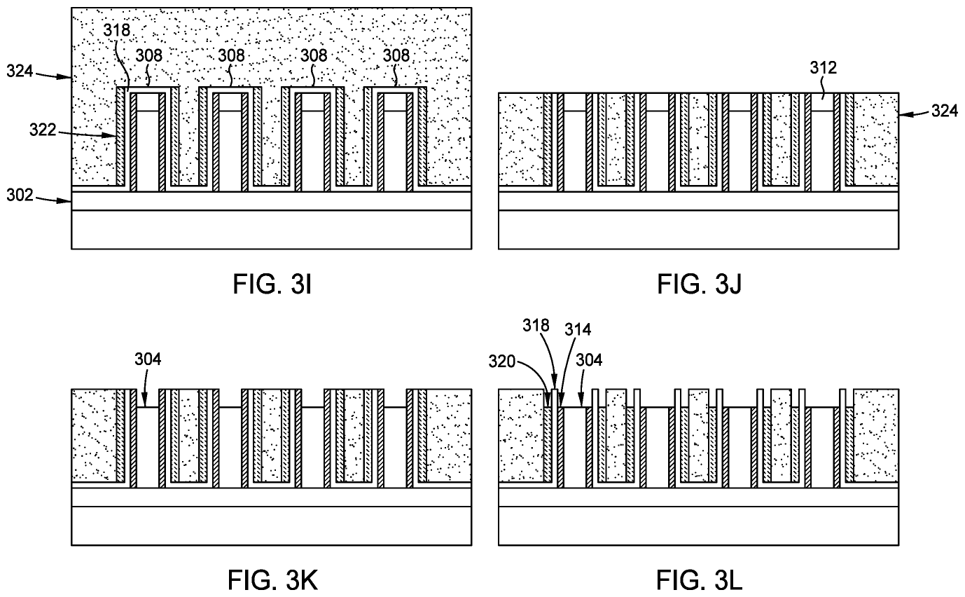

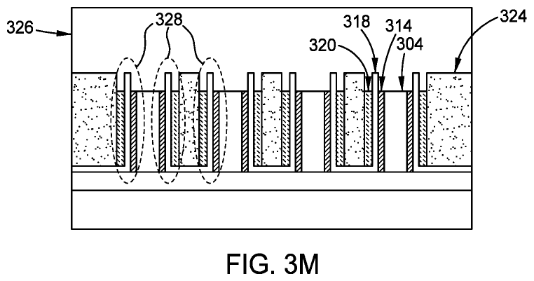

FIGS. 3A-M illustrate example operations for fabricating a vertical RRAM, such as vertical RRAM 200, in accordance with certain aspects of the present disclosure. As illustrated in FIG. 3A, the operations may begin by depositing a silicon dioxide (SiO₂) layer 302 above a substrate layer 300. In some cases, the SiO₂ layer 302 may be approximately 2-10 nm thick. Additionally, in some cases, as noted above, the substrate layer 300 may be made of a material such as silicon, glass, ceramic, aluminum oxide, or any other suitable material. According to aspects, the substrate layer 300 and SiO₂ layer may be collectively referred to as a “substrate.”

As illustrated in FIG. 3B, a layer of tungsten (W) 304 may be deposited above the SiO₂ layer 302. In some cases, the layer of tungsten 304 may be approximately 10-200 nm thick. Additionally, as illustrated, a silicon nitride (Si₃N₄) cap layer 306 may then be deposited above the layer of tungsten 304. For certain aspects, the Si₃N₄ cap layer 306 may be approximately 10 nm thick.

As illustrated in FIG. 3C, a lithographic mask may then be applied, and the Si₃N₄ cap layer 306 and the layer of tungsten 304 may be selectively etched down to the SiO₂ layer 302 according to the lithographic mask, creating a plurality of fins 308. As illustrated, each of the fins 308 may comprise a fin of tungsten 310 capped with a Si₃N₄ cap 312. Although four fins 308 are illustrated in FIG. 3C, it is to be understood that more or less than four fins may be created at this stage and that the remaining operations apply to the number of created fins, whether less than, equal to, or more than four fins.

As illustrated in FIG. 3D, a first electrode layer 314 may then be deposited on exposed surfaces of the SiO₂ layer 302 and fins 308. In some cases, the first electrode layer 314 may be approximately 1-5 nm thick and may comprise titanium nitride (TiN) (e.g., designated “TiN−1” in FIGS. 3D-3M) or any other suitable electrically conductive material.

As illustrated in FIG. 3E, the first electrode layer 314 may then be removed (e.g., etched) from the tops of the fins 308 (e.g., the tops of the Si₃N₄ caps 312) and from the top of the SiO₂ layer 302, leaving the first electrode layer 314 on the sides of the fins 308 as shown at 316.

As illustrated in FIG. 3F, a resistive-switching material layer 318 may be deposited (e.g., by atomic layer deposition (ALD)) on exposed surfaces of the SiO₂ layer 302, the first electrode layer 314, and the Si₃N₄ caps 312. In some cases, the resistive-switching material layer 318 may be approximately 1-5 nm thick and composed of a dielectric material, such as hafnium oxide (HfO₂) or titanium oxide (TiO₂). As noted above, the resistive-switching material layer 318 may serve as a medium for storing logical values (e.g., logical “0” and logical “1”) when a forming voltage is applied.

Thereafter, as illustrated in FIG. 3G, a second electrode layer 320 may be deposited on exposed surfaces of the resistive-switching material layer 318. In some cases, the second electrode layer 320 may be approximately 1-5 nm thick and may comprise titanium nitride (TiN) (e.g., designated “TiN−2” in FIGS. 3G-3M) or any other suitable electrically conductive material.

As illustrated in FIG. 3H, the second electrode layer 320 may then be removed (e.g., etched) from the tops of the fins 308 (e.g., down to the resistive-switching material layer 318 on the fins 308) and from the trenches 321 between the fins 308, leaving the second electrode layer 320 deposited on the sides of the fins 308. For example, as illustrated at 322, the second electrode layer 320 may be removed from the tops of the resistive-switching material layer 318 deposited on the SiO₂ layer in the trenches between the fins 308. Additionally, as illustrated, the resistive-switching material layer 318 may separate the first electrode layer 314 from the second electrode layer 320, as well as the second electrode layer 320 from the SiO₂ layer 302.

As illustrated in FIG. 3I, a first dielectric layer 324 may then be deposited, filling in the trenches between the fins 308 and covering exposed surfaces of the SiO₂ layer 302, the resistive-switching material layer 318, and the second electrode layer 320. In some cases, the first dielectric layer 324 may be approximately 200 nm thick and may comprise a material such as silicon oxynitride (SiOₓN_{y}) or silicon dioxide (SiO₂).

As illustrated in FIG. 3J, chemical-mechanical polishing (CMP) may be performed to remove portions of the first dielectric layer 324 and the resistive-switching material layer 318 down to the Si₃N₄ caps 312.

As illustrated in FIG. 3K, the Si₃N₄ caps 312 may be removed (e.g., by dry etch), exposing an upper surface of the layer of tungsten 304 in each fin 308.

As illustrated in FIG. 3L, the first electrode layer 314 and the second electrode layer 320 may be selectively etched, for example, to a level below a height of the resistive-switching material layer 318, the level being even with the upper surfaces of the layers of tungsten 304.

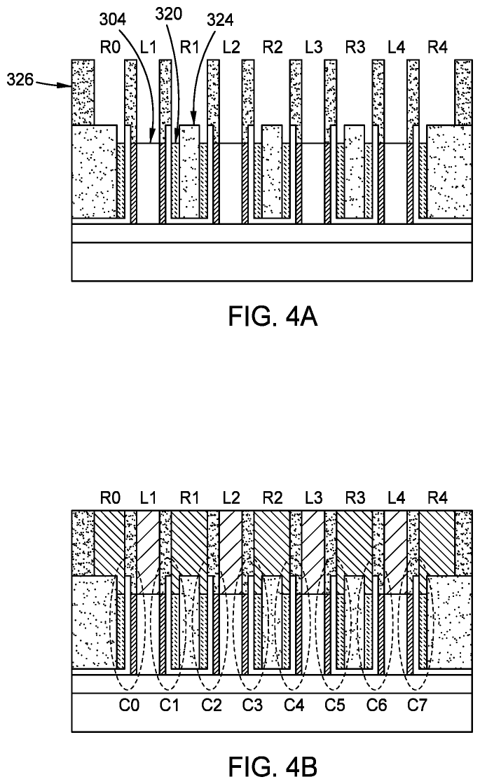

As illustrated in FIG. 3M, a second dielectric layer 326 may then be deposited, covering exposed surfaces of the first dielectric layer 324, second electrode layer 320, resistive-switching material layer 318, first electrode layer 314, and layers of tungsten 304. At this point, potential individual RRAM cells 328 may be clearly seen. For example, as illustrated each RRAM cell 328 may comprise a layered group (e.g., a horizontally stacked MIM structure) of a first electrode layer 314, a resistive-switching material layer 318, and a second electrode layer 320. As illustrated, each RRAM cell 328 may be separated by, for example, a fin of tungsten 304 or the first dielectric layer 324. However, while various potential RRAM cells 328 are illustrated, at this point, no external connections to the RRAM cells 328 have been made. Thus, FIGS. 4-6 illustrate different options for providing connections to the RRAM cells 328.

For example, a first option illustrated in FIGS. 4A-B may involve selectively etching the second dielectric layer 326 to create RRAM cells with one electrode shared between two neighboring RRAM cells. In other words, a memory cell with one neighbor shares one electrode, whereas a memory cell with two neighbors shares one electrode with its neighbor to the left and one electrode with its neighbor to the right. For example, as illustrated in FIG. 4A, contact lithography and double patterning may be applied to selectively etch the second dielectric layer 326 (not including the first dielectric layer 324 or the resistive-switching material layer 318), creating a contact window for connections to the first electrode layer 314 and the second electrode layer 320. For example, as illustrated, the second dielectric layer 326 may be etched down to the fin of tungsten 304 to create contact window L1. Similarly, the second dielectric layer 326 may be etched down to the second electrode layer 320 and the first dielectric layer 324 to create contact window R1 shared between two RRAM cells (e.g., C1 and C2). This pattern of etching may be applied to the second dielectric layer 326 for the remaining fins of tungsten 304 and fins of first dielectric layer 324/second electrode layers 320, as illustrated by contact windows R0, L2, R2, L3, R3, L4, and R4.

Thereafter, as illustrated in FIG. 4B, contact metal (e.g., tungsten) may be filled into the contact windows at R0, L1, R1, L2, R2, L3, R3, L4, and R4. In some cases, the contact metal may be approximately 200 nm thick. Further, as illustrated, this pattern of etching applied to the second dielectric layer 326, for example, when filled with the contact metal creates pairs of neighboring RRAM cells that share an electrode (e.g., that share the layer of tungsten 304 or share the second electrode layer 320). For example, as illustrated, the following pairs of RRAM cells may be formed by this pattern of etching and contact metal filling: C1+C2 (e.g., formed by contact windows L1/R1 and R1/L2), C3+C4 (e.g., formed by contact windows L2/R2 and R2/L3), and C5+C6 (e.g., formed by contact windows L3/R3 and R3/L4). For example, as illustrated, RRAM cells C1 and C2 share the contact metal R1, cells C3 and C4 share the contact metal R2, and cells C5 and C6 share the contact metal R3. Also, RRAM cells C0 and C1 share the contact metal L1, cells C2 and C3 share the contact metal L2, cells C4 and C5 share the contact metal L3, and cells C6 and C7 share the contact metal L4.

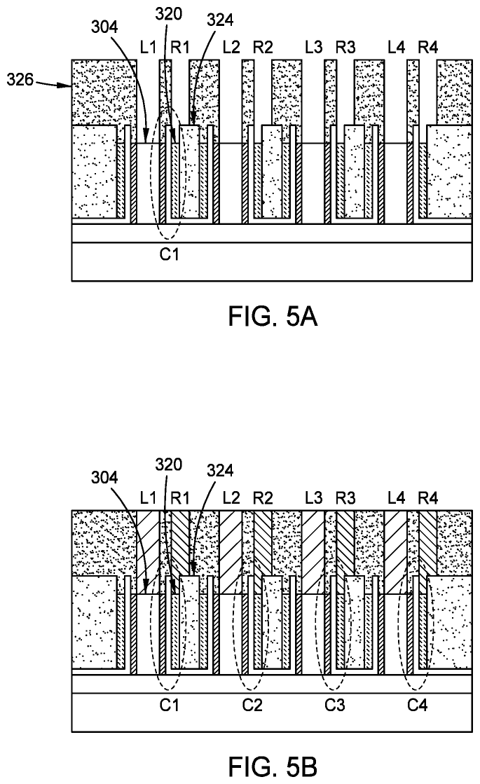

A second option illustrated in FIGS. 5A-B may involve selectively etching the second dielectric layer 326 to create RRAM cells without a shared electrode. For example, as illustrated in FIG. 5A, contact lithography and double patterning may be applied to selectively etch the second dielectric layer 326 (not including the first dielectric layer 324 or the resistive-switching material layer 318), creating a contact window for connections to the first electrode layer 314 and the second electrode layer 320. For example, as illustrated, the second dielectric layer 326 may be etched down to the fin of tungsten 304 to create contact window at L1 (for the left side of memory cell C1). Similarly, the second dielectric layer 326 may be etched down to the second electrode layer 320 and the first dielectric layer 324 to create contact window R1 (for the right side of memory cell C1). As illustrated, however, the contact window R1 may only correspond to one RRAM cell (e.g., C1) and may not be shared with another RRAM cell. This pattern of etching may be applied to the second dielectric layer 326 for the remaining fins of tungsten 304 and fins of first dielectric layer 324/second electrode layers 320, as illustrated by contact windows L2, R2, L3, R3, L4, and R4.

Thereafter, as illustrated in FIG. 5B, contact metal (e.g., tungsten) may be filled into the contact windows at L1, R1, L2, R2, L3, R3, L4, and R4. In some cases, the contact metal may be approximately 200 nm thick. Further, as illustrated, this pattern of etching applied to the second dielectric layer 326, for example, when filled with the contact metal creates RRAM cells that do not share an electrode (e.g., that do not share the layer of tungsten 304 or the second electrode layer 320). For example, as illustrated, the following RRAM cells may be formed by the pattern of etching and contact metal filling illustrated in FIGS. 5A-B: C1 (e.g., formed by contact windows L1/R1), C2 (e.g., formed by contact windows L2/R2), C3 (e.g., formed by contact windows L3/R3), and C4 (e.g., formed by contact windows L4/R4). As illustrated, RRAM cells C1, C2, C3, and C4 do not share an electrode. Further, selectively etching the second dielectric layer 326 as illustrated in FIGS. 5A-5B may form four RRAM cells (e.g., C1-C4), which is half as dense as the memory cells formed in the selective etching illustrated in FIGS. 4A-4B (e.g., C0-C7)

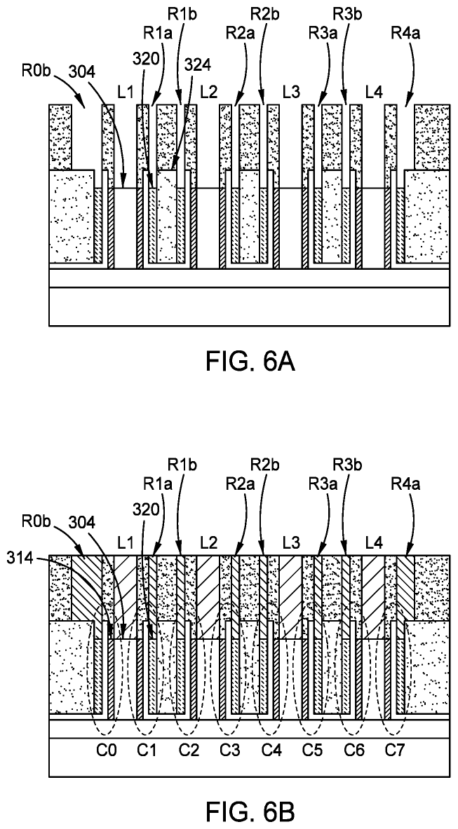

A third option illustrated in FIGS. 6A-B may involve selectively etching the second dielectric layer 326 to create RRAM cells in which each memory cell shares a single electrode with all neighboring memory cells, having a similar density of RRAM cells as illustrated in FIGS. 4A-4B. For example, as illustrated in FIG. 6A, contact lithography and double patterning may be applied to selectively etch the second dielectric layer 326 (not including the first dielectric layer 324 or the resistive-switching material layer 318), creating a contact window for connections to the first electrode layer 314 and the second electrode layer 320. For example, as illustrated, the second dielectric layer 326 may be etched down to the fin of tungsten 304 to create contact window at L1 (e.g., for connection to the first electrode layer 314). Similarly, the second dielectric layer 326 may be etched down to the second electrode layer 320 on a first side of the first dielectric layer 324 to create contact window R1a and etched down to the second electrode layer 320 on a second side of the first dielectric layer 324 to create contact window R1b. This pattern of etching may be applied to the second dielectric layer 326 for the remaining fins of tungsten 304 and second electrode layers 320, as illustrated by contact windows R0b, L2, R2a, R2b, L3, R3a, R3b, L4, and R4a. As illustrated, this pattern of etching may create independent contact windows for each second electrode layer 320 of different RRAM cells, rather than having a shared contact window for the second electrode layer 320 between two neighboring RRAM cells. Accordingly, such a pattern of etching may allow for a higher RRAM cell density (e.g., similar to FIGS. 4A-4B), while maintaining separate electrodes for each of the RRAM cells (e.g., similar to FIGS. 5A-5B).

Thereafter, as illustrated in FIG. 6B, contact metal (e.g., tungsten) may be filled into the contact windows at R0b, L1, R1a, R1b, L2, R2a, R2b, L3, R3a, R3b, L4, and R4a. In some cases, the contact metal may be approximately 200 nm thick. Further, as illustrated, this pattern of etching applied to the second dielectric layer 326, for example, when filled with the contact metal creates RRAM cells that share an electrode (e.g., that share the first electrode layer 314 and the layer of tungsten 304), but that do not share a second electrode (e.g., second electrode layer 320). For example, as illustrated, the following RRAM cells may be formed by pattern of etching and contact metal filling illustrated in FIGS. 6A-B: C0 (e.g., formed by contact windows R0b/L1), C1 (e.g., formed by contact windows L1/R1a), C2 (e.g., formed by contact windows L2/R1b), and C3 (e.g., formed by contact windows L2/R2a), and C4 (e.g., formed by contact windows L3/R2b), C5 (e.g., formed by contact windows L3/R3a), C6 (e.g., formed by contact windows L4/R3b), and C7 (e.g., formed by contact windows L4/R4a). As illustrated, RRAM cells C1-C7 share an electrode, for example, the first electrode layer 314 (e.g., via the tungsten fin 304), but do not share the second electrode layer 320.

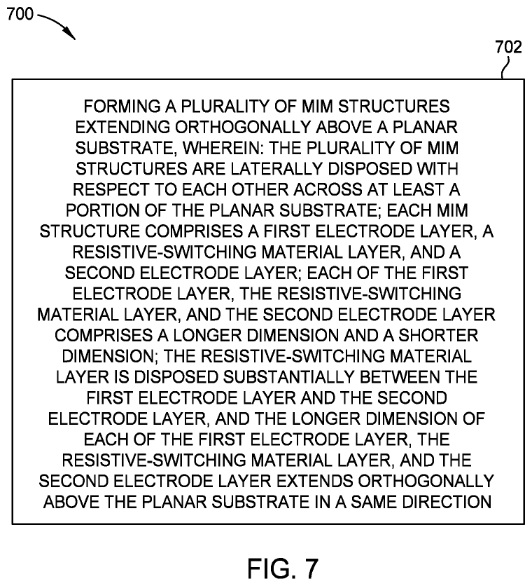

FIG. 7 is a flow diagram illustrating example operations 700 for fabricating a vertical resistive random access memory (RRAM) device, in accordance with certain aspects of the present disclosure. The operations 700 may be performed, for example, by a semiconductor processing facility.

The operations 700 begin, at block 702, with the semiconductor processing facility forming a plurality of metal-insulator-metal (MIM) structures extending orthogonally above a planar substrate. In some cases, the plurality of MIM structures are laterally disposed with respect to each other across at least a portion of the planar substrate. In some cases, each MIM structure comprises a first electrode layer, a resistive-switching material layer, and a second electrode layer. Additionally, in some cases, each of the first electrode layer, the resistive-switching material layer, and the second electrode layer comprises a longer dimension and a shorter dimension. Additionally, in some cases, the resistive-switching material layer is disposed substantially between the first electrode layer and the second electrode layer. Further, in some cases, the longer dimension of each of the first electrode layer, the resistive-switching material layer, and the second electrode layer extends orthogonally above the planar substrate in a same direction

In some cases, operations 700 may also include forming the planar substrate by depositing a second substrate layer above a first substrate layer. In some cases, the first layer comprises one of silicon, glass, ceramic, or aluminum oxide. Additionally, in some cases, the second layer comprises silicon dioxide.

Additionally, in some cases, forming the plurality of MIM structures comprises depositing a metal layer above the planar substrate and depositing a cap layer above the metal layer. For certain aspects, the metal layer may comprise tungsten (W). For certain aspects, the cap layer may comprise silicon nitride (Si₃N₄).

In some cases, forming the plurality of MIM structures further comprises etching, down to the planar substrate, the metal layer, and the cap layer to form a plurality of metal fins capped with the cap layer.

In some cases, forming the plurality of MIM structures further comprises depositing the first electrode layer on exposed surfaces of the planar substrate and the plurality of metal fins capped with the cap layer and removing the first electrode layer from the planar substrate and a top side of each of the plurality of metal fins capped with the cap layer.

In some cases, forming the plurality of MIM structures further comprises depositing the resistive-switching material layer on exposed surfaces of the planar substrate, the first electrode layer, and the top side of each of the plurality of metal fins capped with the cap layer and depositing the second electrode layer on exposed surfaces of the resistive-switching material layer.

In some cases, forming the plurality of MIM structures further comprises filling in trenches between the plurality of metal fins capped with the cap layer with a first dielectric layer, wherein the first dielectric layer is deposited between, and separates, each MIM structure of the plurality of MIM structures. According to aspects, the first dielectric layer may then be removed down to the caps. Further, in some cases, the caps may then be removed from the plurality of metal fins. Additionally, upper portions of the first and second electrode layers may be removed (e.g., down to upper surfaces of the metal layer). Thereafter, a second dielectric layer may be deposited on exposed surfaces of the first dielectric layer, the first electrode layer, the resistive-switching material layer, the second electrode layer, and the plurality of metal fins. Further, the second dielectric layer may then be etched to form trenches for electrical connections to the first electrode layer and the second electrode layer.

In some cases, the second electrode layer of a first MIM structure of the plurality of MIM structures is connected to the second electrode layer of a second MIM structure of the plurality of MIM structures by a same electrode.

In some cases, at least one of the first electrode layer or the second electrode layer comprises titanium nitride. Additionally, in some cases, the resistive-switching material layer comprises hafnium oxide or titanium oxide.

In some cases, the first electrode layer and the resistive-switching material layer are disposed directly adjacent to the substrate layer. Additionally, in some cases, the resistive-switching material layer separates the second electrode layer from the substrate layer.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

What is claimed is:

1. A resistive random access memory (RRAM), comprising:
a planar substrate; and
a plurality of metal-insulator-metal (MIM) structures extending orthogonally above the planar substrate, wherein:
the plurality of MIM structures are laterally disposed with respect to each other across at least a portion of the planar substrate;
each MIM structure comprises a first electrode layer, a resistive-switching material layer, and a second electrode layer;
each of the first electrode layer, the resistive-switching material layer, and the second electrode layer comprises a longer dimension and a shorter dimension;
the resistive-switching material layer is disposed substantially between the first electrode layer and the second electrode layer; and
the longer dimension of each of the first electrode layer, the resistive-switching material layer, and the second electrode layer extends orthogonally above the planar substrate in a same direction.

2. The RRAM of claim 1, wherein a first dielectric layer is disposed between, and separates, each MIM structure of the plurality of MIM structures.

3. The RRAM of claim 1, wherein the second electrode layer of a first MIM structure of the plurality of MIM structures is connected to the second electrode layer of a second MIM structure of the plurality of MIM structures by a same electrode for external connection.

4. The RRAM of claim 1, wherein at least one of the first electrode layer or the second electrode layer comprises titanium nitride.

5. The RRAM of claim 1, wherein the resistive-switching material layer comprises hafnium oxide or titanium oxide.

6. The RRAM of claim 1, wherein:
the planar substrate comprises a first substrate layer and a second substrate layer disposed above the first substrate layer;
the first substrate layer comprises one of silicon, glass, ceramic, or aluminum oxide; and
the second substrate layer comprises silicon dioxide.

7. The RRAM of claim 1, wherein the first electrode layer and the resistive-switching material layer are disposed directly adjacent to the planar substrate and wherein the resistive-switching material layer separates the second electrode layer from the planar substrate.

8. The RRAM of claim 1, further comprising a number of electrodes for external connection, wherein the number of electrodes for external connection is greater than or equal to a number of the plurality of MIM structures.

9. A method for fabricating a vertical resistive random access memory (RRAM), the method comprising forming a plurality of metal-insulator-metal (MIM) structures extending orthogonally above a planar substrate, wherein:
the plurality of MIM structures are laterally disposed with respect to each other across at least a portion of the planar substrate;
each MIM structure comprises a first electrode layer, a resistive-switching material layer, and a second electrode layer;
each of the first electrode layer, the resistive-switching material layer, and the second electrode layer comprises a longer dimension and a shorter dimension;
the resistive-switching material layer is disposed substantially between the first electrode layer and the second electrode layer; and
the longer dimension of each of the first electrode layer, the resistive-switching material layer, and the second electrode layer extends orthogonally above the planar substrate in a same direction.

10. The method of claim 9, further comprising forming the planar substrate by depositing a second substrate layer above a first substrate layer, wherein:
the first substrate layer comprises one of silicon, glass, ceramic, or aluminum oxide; and
the second substrate layer comprises silicon dioxide.

11. The method of claim 9, wherein forming the plurality of MIM structures comprises:
depositing a metal layer above the planar substrate; and
depositing a cap layer above the metal layer.

12. The method of claim 11, wherein forming the plurality of MIM structures further comprises:
etching, down to the planar substrate, the metal layer, and the cap layer to form a plurality of metal fins capped with the cap layer.

13. The method of claim 12, wherein forming the plurality of MIM structures further comprises:
depositing the first electrode layer on exposed surfaces of the planar substrate and the plurality of metal fins capped with the cap layer; and
removing the first electrode layer from the planar substrate and a top side of each of the plurality of metal fins capped with the cap layer.

14. The method of claim 13, wherein forming the plurality of MIM structures further comprises:
depositing the resistive-switching material layer on exposed surfaces of the planar substrate, the first electrode layer, and the top side of each of the plurality of metal fins capped with the cap layer; and
depositing the second electrode layer on exposed surfaces of the resistive-switching material layer.

15. The method of claim 14, wherein forming the plurality of MIM structures further comprises:
filling in trenches between the plurality of metal fins capped with the cap layer with a first dielectric layer, wherein the first dielectric layer is deposited between, and separates, each MIM structure of the plurality of MIM structures;
removing the first dielectric layer down to upper surfaces of the cap layer;
removing the cap layer from the plurality of metal fins;
removing upper portions of the first and second electrode layers down to upper surfaces of the metal layer;
depositing a second dielectric layer on exposed surfaces of the first dielectric layer, the first electrode layer, the resistive-switching material layer, the second electrode layer, and the plurality of metal fins; and
selectively etching the second dielectric layer to form trenches for electrical connections to the first electrode layer and the second electrode layer.

16. The method of claim 9, wherein the second electrode layer of a first MIM structure of the plurality of MIM structures is connected to the second electrode layer of a second MIM structure of the plurality of MIM structures by a same electrode.

17. The method of claim 9, wherein at least one of the first electrode layer or the second electrode layer comprises titanium nitride.

18. The method of claim 9, wherein the resistive-switching material layer comprises hafnium oxide or titanium oxide.

19. The method of claim 9, wherein the first electrode layer and the resistive-switching material layer are disposed directly adjacent to the planar substrate.

20. The method of claim 19, wherein the resistive-switching material layer separates the second electrode layer from the planar substrate.
